(19) United States
(12) Patent Application Publication
(10) Pub. No.: US 2025/0287609 A1
(43) Pub. Date: Sep. 11, 2025

(54) METHOD OF FABRICATING VARIABLE RESISTANCE MEMORY DEVICE

(71) Applicant: Samsung Electronics Co., Ltd., Suwon-si (KR)

(72) Inventors: Junhoe Kim, Suwon-si (KR); Kyounghun Ryu, Suwon-si (KR); Junho Park, Suwon-si (KR); Byoungjae Bae, Suwon-si (KR); Kilho Lee, Suwon-si (KR); Jihyeon Jeon, Suwon-si (KR); Hyeonah Jo, Suwon-si (KR)

(21) Appl. No.: 19/074,625

(22) Filed: Mar. 10, 2025

(30) Foreign Application Priority Data
Mar. 11, 2024 (KR) 10-2024-0033865

(51) Int. Cl. H10B 61/00; G11C 11/16; H10N 50/10; H10N 50/80

(52) U.S. Cl. CPC H10B 61/22; G11C 11/161; H10N 50/10; H10N 50/80; G11C 11/1673; G11C 11/1675

(57) ABSTRACT

According to the method of fabricating a variable resistance memory device, by forming a mold insulation layer from materials with similar etch selectivity in the cell area and the peripheral area, the difference between etch profiles that occurs during formation of the first contact hole and the second contact hole simultaneously in the cell area and the peripheral area may be reduced.

### CROSS-REFERENCE TO RELATED APPLICATION

This application is based on and claims priority under 35 U.S.C. § 119 to Korean Patent Application No. 10-2024-0033865, filed on Mar. 11, 2024, in the Korean Intellectual Property Office, the disclosure of which is incorporated by reference herein in its entirety.

### BACKGROUND

The inventive concept relates to a method of fabricating a variable resistance memory device, and more particularly, to a method of fabricating a variable resistance memory device including a magnetic tunnel junction (MTJ) structure.

Recently, as electronic products exhibit high speed and low power consumption, fast read/write operations and low operating voltages of semiconductor devices embedded in the electronic products are more in demand. In response to this increased demand, highly integrated variable resistance memory devices are emerging as next-generation memory devices because they enable high-speed read and high-speed write operations and are non-volatile. In particular, research is being conducted on variable resistance memory devices that utilize the magnetoresistance characteristics of a magnetic tunnel junction (MTJ).

### SUMMARY

The inventive concept provides a method of fabricating a variable resistance memory device capable of reducing the difference between etch profiles that occurs during simultaneous formation of contact holes in a cell area and a peripheral area by forming mold insulation layers using materials with similar etch selectivity in the cell area and the peripheral area.

In addition, the technical goals to be achieved by embodiments of the inventive concept are not limited to the technical goals mentioned above, and other technical goals may be clearly understood by one of ordinary skill in the art from the following descriptions.

According to an aspect of the inventive concept, there is provided a method of fabricating a variable resistance memory device, the method comprising preparing a substrate having a cell area and a peripheral area surrounding the cell area in a plan view, forming a first plug comprising a first cell plug and a first via plug in the cell area and forming a second plug in the peripheral area, forming a lower insulation layer on the first plug and the second plug over the cell area and the peripheral area, forming a magnetic tunnel junction (MTJ) structure that extends through the lower insulation layer in the cell area and is electrically connected to the first cell plug, forming a capping layer conformally on the MTJ structure and the lower insulation layer over the cell area and the peripheral area, forming a capping pattern on both sidewalls of the MTJ structure by anisotropically etching the capping layer in the cell area, forming a buried insulation layer on the MTJ structure in the cell area and removing the capping layer from the peripheral area, forming an interlayer insulation layer on the lower insulation layer in the peripheral area, forming an upper insulation layer on the buried insulation layer in the cell area and on the interlayer insulation layer in the peripheral area, forming a first via hole overlapping the first plug in the cell area in a direction perpendicular to an upper surface of the substrate and forming a second via hole overlapping the second plug in the peripheral area in the direction perpendicular to the upper surface of the substrate, and forming a first contact hole by etching a bottom surface of the first via hole that overlaps the first via plug in the cell area in the direction perpendicular to the substrate and forming a second contact hole by etching a bottom surface of the second via hole in the peripheral area.

According to another aspect of the inventive concept, there is provided a method of fabricating a variable resistance memory device, the method comprising preparing a substrate having a cell area and a peripheral area surrounding the cell area in a plan view, forming a first plug comprising a first cell plug and a first via plug in the cell area and forming a second plug in the peripheral area, forming a lower insulation layer on the first plug and the second plug over the cell area and the peripheral area, forming a magnetic tunnel junction (MTJ) structure that extends through the lower insulation layer in the cell area and is electrically connected to the first cell plug, forming a capping layer conformally on the MTJ structure and the lower insulation layer over the cell area and the peripheral area, forming a mask pattern over the cell area and the peripheral area to at least partially expose an area overlapping the first via plug in a direction perpendicular to the upper surface of the substrate, at least partially exposing a lower insulation layer in the area overlapping the first via plug in the direction perpendicular to the upper surface of the substrate by etching a portion of the capping layer by using the mask pattern as an etching mask, removing the mask pattern, forming a buried insulation layer on the MTJ structure in the cell area and removing the capping layer from the peripheral area, forming an interlayer insulation layer on the lower insulation layer in the peripheral area, forming an upper insulation layer on the buried insulation layer in the cell area and on the interlayer insulation layer in the peripheral area, forming a first via hole overlapping the first plug in the cell area in the direction perpendicular to the upper surface of the substrate and forming a second via hole overlapping the second plug in the peripheral area in the direction perpendicular to the upper surface of the substrate, and forming a first contact hole by etching a bottom surface of the first via hole that overlaps the first via plug in the cell area in the direction perpendicular to the upper surface of the substrate and forming a second contact hole by etching a bottom surface of the second via hole in the peripheral area.

According to another aspect of the inventive concept, there is provided a method of fabricating a variable resistance memory device, the method comprising preparing a substrate having a cell area and a peripheral area surrounding the cell area in a plan view, forming a first plug comprising a first cell plug and a first via plug in the cell area and forming a second plug in the peripheral area, forming a lower insulation layer on the first plug and the second plug over the cell area and the peripheral area, forming a magnetic tunnel junction (MTJ) structure that extends through the lower insulation layer in the cell area and is electrically connected to the first cell plug, forming a capping layer conformally on the MTJ structure and the lower insulation layer over the cell area and the peripheral area, etching a portion of the capping layer to at least partially expose a lower insulation layer in an area overlapping the first via plug in a direction perpendicular to an upper surface of the substrate, forming a buried insulation layer on the MTJ structure in the cell area and removing the capping layer from the peripheral area, forming an interlayer insulation layer on the lower insulation layer in the peripheral area, forming an upper insulation layer on the buried insulation layer in the cell area and on the interlayer insulation layer in the peripheral area, forming a first via hole overlapping the first plug in the cell area in the direction perpendicular to the upper surface of the substrate and forming a second via hole overlapping the second plug in the peripheral area in the direction perpendicular to the upper surface of the substrate, forming a first contact hole by etching a bottom surface of the first via hole that overlaps the first via plug in the cell area in the direction perpendicular to the upper surface of the substrate and forming a second contact hole by etching a bottom surface of the second via hole in the peripheral area, forming a metal layer that at least partially fills the first via hole and the first contact hole in the cell area and at least partially fills the second via hole and the second contact hole in the peripheral area, and separating the metal layer into nodes to form a first contact in contact with the MTJ structure and a cell via in contact with the first via plug in the cell area, and forming a second contact in contact with the second plug in the peripheral area.

### BRIEF DESCRIPTION OF THE DRAWINGS

Embodiments of the inventive concept will be more clearly understood from the following detailed description taken in conjunction with the accompanying drawings in which:

FIG. 1 is a circuit diagram illustrating a cell array of a variable resistance memory device according to an embodiment;

FIG. 2 is a circuit diagram illustrating a magnetoresistive memory cell of FIG. 1;

FIG. 3 is a perspective view of the magnetoresistive memory cell of FIG. 2;

FIG. 4 is a plan view illustrating a variable resistance memory device according to an embodiment;

FIG. 5 is a flowchart of a method of fabricating a variable resistance memory device according to an embodiment;

FIGS. 6 to 16 are cross-sectional views illustrating a method of fabricating a variable resistance memory device according to an embodiment according to a process sequence;

FIG. 17 is a flowchart of a method of fabricating a variable resistance memory device according to another embodiment;

FIGS. 18 to 22 are cross-sectional views illustrating a method of fabricating a variable resistance memory device according to another embodiment according to a process sequence;

FIG. 23 is a configuration diagram illustrating a data processing system including a variable resistance memory element according to an embodiment; and

FIG. 24 is a configuration diagram illustrating a data processing system including a variable resistance memory element according to an embodiment.

### DETAILED DESCRIPTION OF THE EMBODIMENTS

The following will now describe some embodiments of the present inventive concepts with reference to the accompanying drawings. Like reference numerals may indicate like components throughout the description. As used herein, the term “and/or” includes any and all combinations of one or more of the associated listed items. It will be understood that, although the terms “first,” “second,” “upper portion,” “lower portion,” etc. may be used herein to describe various elements or components, these elements or components should not be limited by these terms. These terms are only used to distinguish one element or component from another element or component. Therefore, a first element or component discussed below could be termed a second element or component. It is noted that aspects described with respect to one embodiment may be incorporated in different embodiments although not specifically described relative thereto. That is, all embodiments and/or features of any embodiments can be combined in any way and/or combination.

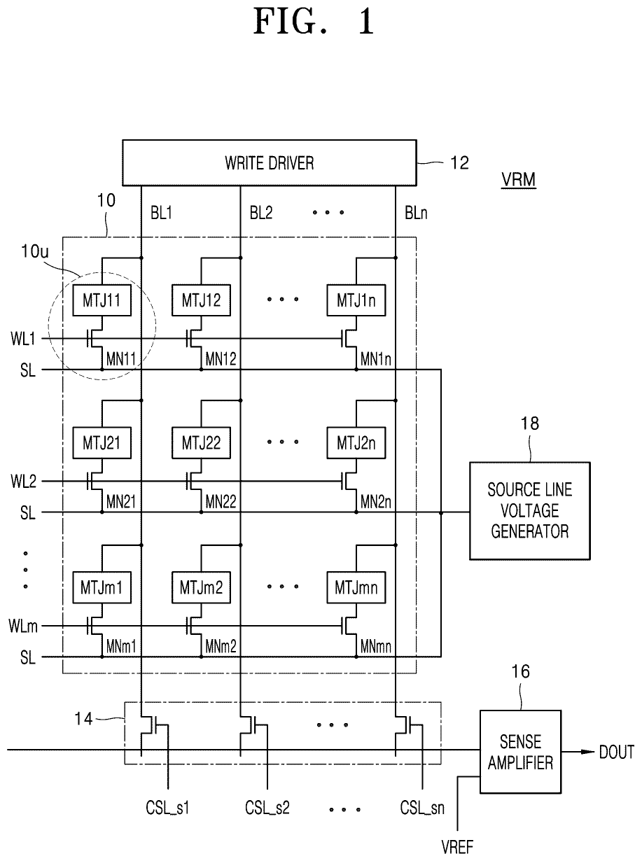

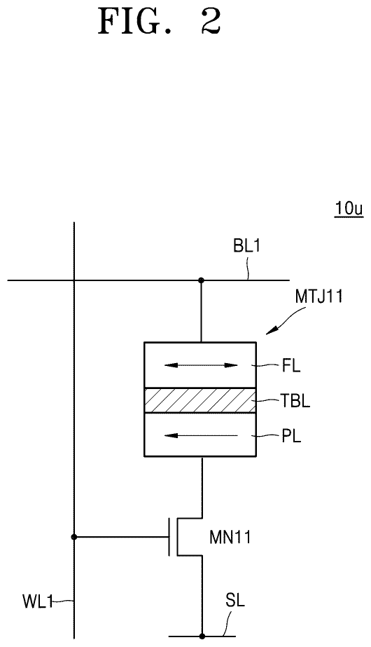

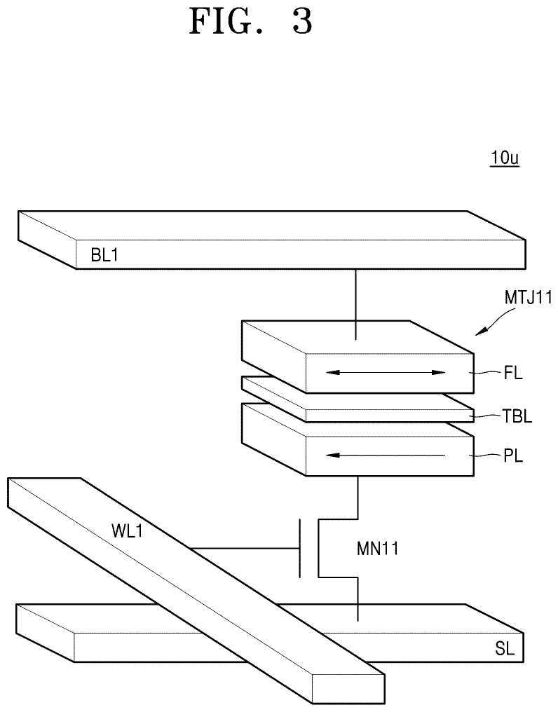

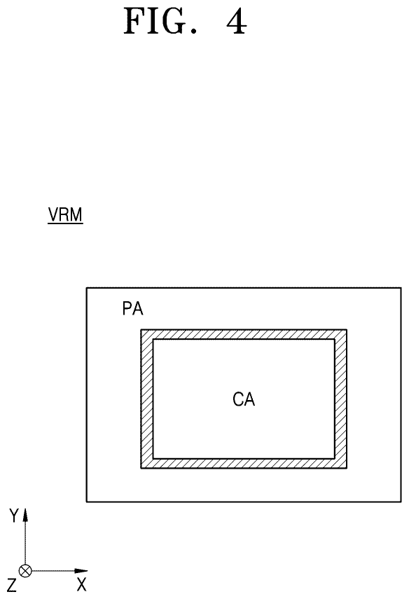

FIG. 1 is a diagram illustrating a cell array of a variable resistance memory device according to an embodiment. FIG. 2 is a circuit diagram illustrating a magnetoresistive memory cell of FIG. 1. FIG. 3 is a perspective view of the magnetoresistive memory cell of FIG. 2. FIG. 4 is a plan view illustrating a variable resistance memory device according to an embodiment.

Referring to FIGS. 1 to 4 together, a variable resistance memory device VRM may be a magnetoresistive memory device according to an embodiment.

As shown in FIG. 1, the variable resistance memory device may be a magnetoresistive RAM (MRAM). The variable resistance memory device VRM may include a magnetic tunnel junction (MTJ), which is a variable resistance layer.

The variable resistance memory device VRM may include a magnetoresistive memory cell array 10. The magnetoresistive memory cell array 10 may also be referred to as a cell array 10. The magnetoresistive memory cell array 10 may be electrically connected to a write driver 12, a select circuit 14, a source line voltage generator 18, and a sense amplifier 16.

The magnetoresistive memory cell array 10 may include a plurality of magnetoresistive memory cells 10u. The magnetoresistive memory cells 10u may be simply referred to as memory cells. The magnetoresistive memory cell array 10 may include a plurality of word lines WL1 to WLm and a plurality of bit lines BL1 to BLn. The magnetoresistive memory cell array 10 may have a magnetoresistive memory cell 10u between each of the word lines WL1 to WLm and each of the bit lines BL1 to BLn.

The magnetoresistive memory cell array 10 may include a plurality of cell transistors MN11 to MNmn, which have gates connected to the plurality of word lines WL1 to WLm, and a plurality of MTJs MTJ11 to MTJmn, which are respectively connected between the plurality of cell transistors MN11 to MNmn and the plurality of bit lines BL1 to BLn and constitute a variable resistance layer.

The write driver 12 is connected to the plurality of bit lines BL1 to BLn, generates a program current based on write data, and provides the program current to the plurality of bit lines BL1 to BLn.

The select circuit 14 may selectively connect the plurality of bit lines BL1 to BLn to the sense amplifier 16 in response to a plurality of column select signals CSL_s1 to CSL_sn. The sense amplifier 16 may generate output data DOUT by amplifying the difference between an output voltage signal of the select circuit 14 and a reference voltage VREF.

Source terminals of the plurality of cell transistors MN11 to MNmn may be connected to the source line SL. To magnetize the plurality of MTJs MTJ11 to MTJmn in the magnetoresistive memory cell array 10, a voltage higher than the voltage applied to the plurality of bit lines BL1 to BLn may be applied to the source line SL. The source line voltage generator 18 may generate a source line driving voltage VSL and provide the source line driving voltage VSL to the source line SL of the magnetoresistive memory cell array 10.

As shown in FIG. 2, the magnetoresistive memory cell 10u may include, for example, a cell transistor MN11 configured as an NMOS transistor and the MTJ MTJ11. The cell transistor MN11 has a gate connected to a word line WL1 and a source connected to the source line SL. The MTJ MTJ11 is connected between a drain of the cell transistor MN11 and the bit line BL1.

As shown in FIG. 3, the MTJ MTJ11 includes a pinned layer PL having a fixed magnetization direction, a free layer FL magnetized in a direction of a magnetic field applied from the outside, and a tunnel barrier layer TBL formed as an insulation layer between the pinned layer PL and the free layer FL.

According to some embodiments, the pinned layer PL may include any one of iron manganese (FeMn), iridium manganese (IrMn), platinum manganese (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), chromium (Cr), iron (Fe), nickel (Ni), cobalt (Co), ruthenium (Ru), iridium (Ir), and/or rhodium (Rh).

According to some embodiments, the free layer FL may be a ferromagnetic material including iron (Fe), nickel (Ni), and/or cobalt (Co).

According to some embodiments, the tunnel barrier layer TBL may include aluminum oxide (AlO) and/or magnesium oxide (MgO).

The MTJ MTJ11 may be included in a memory cell that constitutes spin transfer torque (STT)-MRAM.

For a write operation of STT-MRAM, a logic high voltage may be applied to the word line WL1 to turn on the cell transistor MN11, and a write current may be applied between the bit line BL1 and the source line SL.

For a read operation of STT-MRAM, a logic high voltage may be applied to the word line WL1 to turn on the cell transistor MN11, and a read current may be applied from the bit line BL1 to the source line SL, thereby determining data stored in the magnetoresistive memory cell 10u according to the resistance value of the MTJ MTJ11 with respect to the read current.

The resistance value of the MTJ MTJ11 varies depending on the magnetization direction of the free layer FL. For example, in the MTJ MTJ11, the magnetization direction of the free layer FL and the magnetization direction of the pinned layer PL may be arranged in parallel with each other. In this case, the MTJ MTJ11 may have a low resistance value and may read out data (e.g., 0). Also, the MTJ MTJ11 may be arranged such that the magnetization direction of the free layer FL is antiparallel to the magnetization direction of the pinned layer PL. In this case, the MTJ MTJ11 has a high resistance value and may read out data (e.g., 1).

Here, the MTJ MTJ11 is shown as a horizontal magnetic element including the free layer FL and the pinned layer PL having horizontal magnetization directions. However, according to other embodiments, a vertical magnetic element including the free layer FL and the pinned layer PL having vertical magnetization directions may also be used.

As shown in FIG. 4, the variable resistance memory device VRM may include a cell area CA and a peripheral area PA surrounding the cell area CA in a plan view. According to some embodiments, the variable resistance memory device VRM may include a boundary area between the cell area CA and the peripheral area PA.

The cell area CA may include an area where the magnetoresistive memory cell array 10 of FIG. 1 is disposed. Also, the cell area CA may be an area where the magnetoresistive memory cell 10u described with reference to FIGS. 1 and 2 is disposed.

In the peripheral area PA, peripheral circuits and peripheral transistors that control the magnetoresistive memory cell array 10 in the cell area CA may be arranged. In other words, the peripheral area PA may be an area where core/peripheral circuits are arranged.

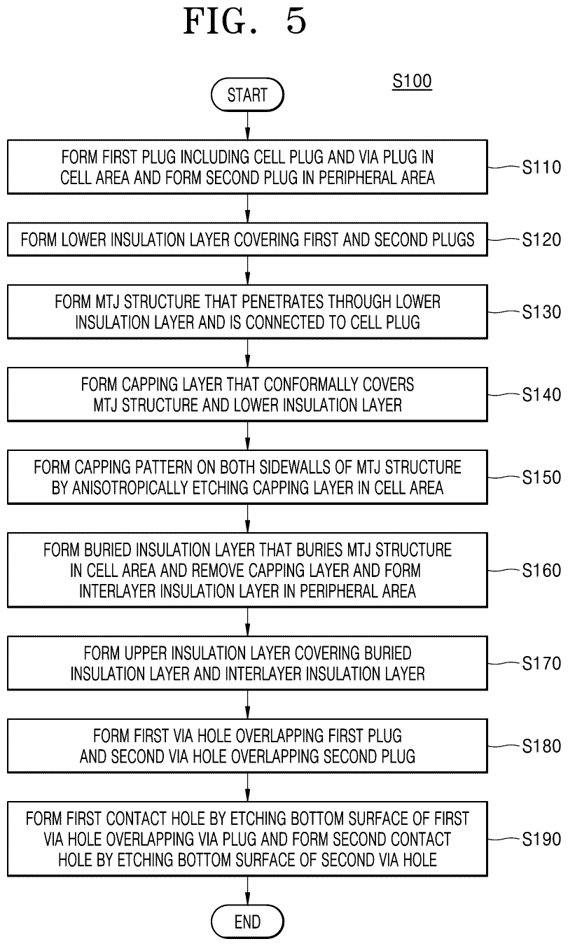

FIG. 5 is a flowchart of a method of fabricating a variable resistance memory device according to an embodiment.

Referring to FIG. 5, a method S100 of fabricating a variable resistance memory device may include first to ninth operations S110 to S190.

In other embodiments, particular operations may be performed in an order different from that described below. For example, two successively described operations may be performed substantially and simultaneously or may be performed in an order opposite to the order described below.

The method S100 of fabricating a variable resistance memory device according to the inventive concept may include a first operation S110 of forming a first plug including a first cell plug and a first via plug in a cell area and forming a second plug in a peripheral area, a second operation S120 of forming a lower insulation layer on and at least partially covering the first plug and the second plug, a third operation S130 of forming an MTJ structure that penetrates or extends through the lower insulation layer and is connected to the first cell plug, a fourth operation S140 of forming a capping layer that conformally is on and at least partially covers the MTJ structure and the lower insulation layer, a fifth operation S150 of forming a capping pattern on both sidewalls of the MTJ structure by anisotropically etching the capping layer in the cell area, a sixth operation S160 of forming a buried insulation layer that is on the MTJ structure in the cell area and removing the capping layer and forming an interlayer insulation layer in the peripheral area, a seventh operation S170 of forming an upper insulation layer that is on and at least partially covers the buried insulation layer and the interlayer insulation layer, an eighth operation S180 of forming a first via hole overlapping the first plug in a vertical direction, i.e., a direction perpendicular to an upper surface of a substrate on which the variable resistance memory device is formed and the cell area distinguished from the peripheral area, and a second via hole overlapping the second plug in the vertical direction, and a ninth operation S190 of forming a first contact hole by etching the bottom surface of the first via hole overlapping the first via plug in the vertical direction and forming a second contact hole by etching the bottom surface of the second via hole.

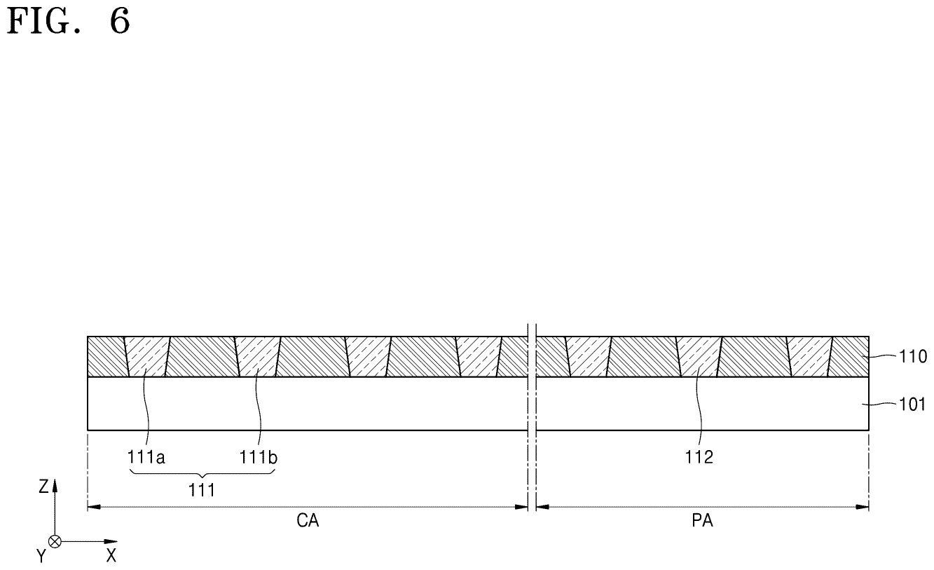

The technical features of first to ninth operations S110 to S190 are described below in detail with reference to FIGS. 6 to 16.

FIGS. 6 to 16 are cross-sectional views illustrating a method of fabricating a variable resistance memory device according to an embodiment according to a process sequence.

Referring to FIG. 6, a substrate 101 in which the cell area CA is distinguished from the peripheral area PA may be prepared.

The substrate 101 may be a semiconductor wafer including silicon (Si), germanium (Ge), silicon carbide (SiC), gallium arsenide (GaAs), indium arsenide (InAs), and/or indium phosphide (InP). According to some embodiments, the substrate 101 may include a conductive region, e.g., a well doped with an impurity or a structure doped with an impurity.

Although not shown, a cell transistor may be formed on the substrate 101 in the cell area CA. The cell transistor may be configured as a buried gate-type transistor. Also, a peripheral circuit transistor may be formed on the substrate 101 in the peripheral area PA. The peripheral circuit transistor may be configured as a planar-type transistor.

A base insulation layer 110 may be formed on the substrate 101, and a plurality of first plugs 111 and a plurality of second plugs 112 penetrating or extending through the base insulation layer 110 may be formed.

In detail, the plurality of first plugs 111 connected to the cell transistor or to a lower metal line (not shown) may be formed in the cell area CA. The plurality of first plugs 111 may include a cell plug 111a and a via plug 111b. The cell plug 111a may be electrically connected to the cell transistor, and the via plug 111b may be electrically connected to the lower metal line. Also, the plurality of second plugs 112 electrically connected to the peripheral circuit transistor may be formed in the peripheral area PA.

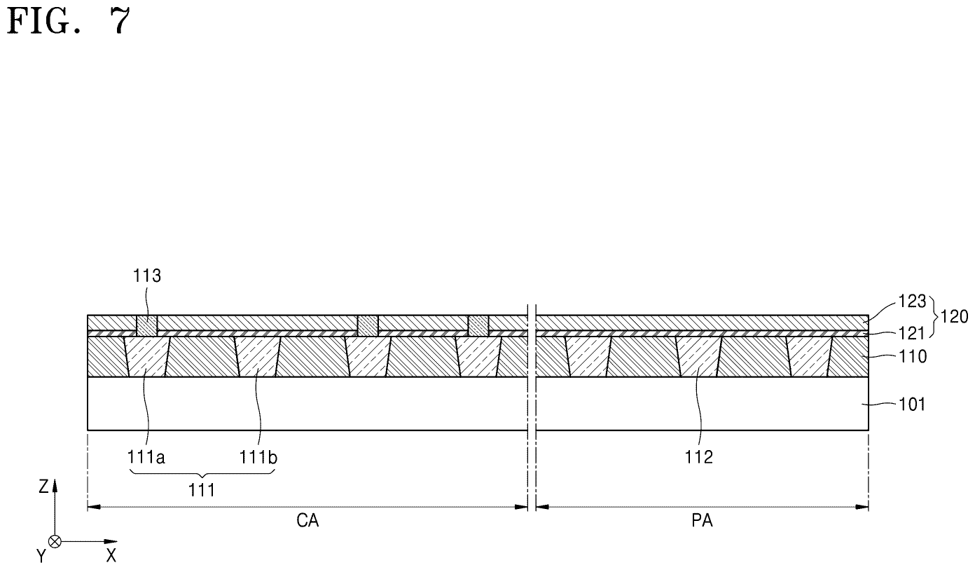

Referring to FIG. 7, a lower insulation layer 120 on and at least partially covering the plurality of first plugs 111 and the plurality of second plugs 112 may be formed over the cell area CA and the peripheral area PA.

The lower insulation layer 120 may include a first lower insulation layer 121 and a second lower insulation layer 123 formed on the first lower insulation layer 121. The first lower insulation layer 121 and the second lower insulation layer 123 may include different materials.

According to some embodiments, the first lower insulation layer 121 may include a SiCN film, a SiOC film, a SiOF film, a SiCH film, a SiOCH film, or a combination thereof.

According to some embodiments, the second lower insulation layer 123 may include a tetraethoxysilane (TEOS) film, but is not limited thereto.

Next, in the cell area CA, a pad electrode 113 that penetrates or extends through the lower insulation layer 120 and contacts and is electrically connected to the cell plug 111a may be formed. Here, the pad electrode 113 is formed only on the cell plug 111a from among the plurality of first plugs 111 and may not be formed on the via plug 111b from among the plurality of first plugs 111 and the plurality of second plugs 112.

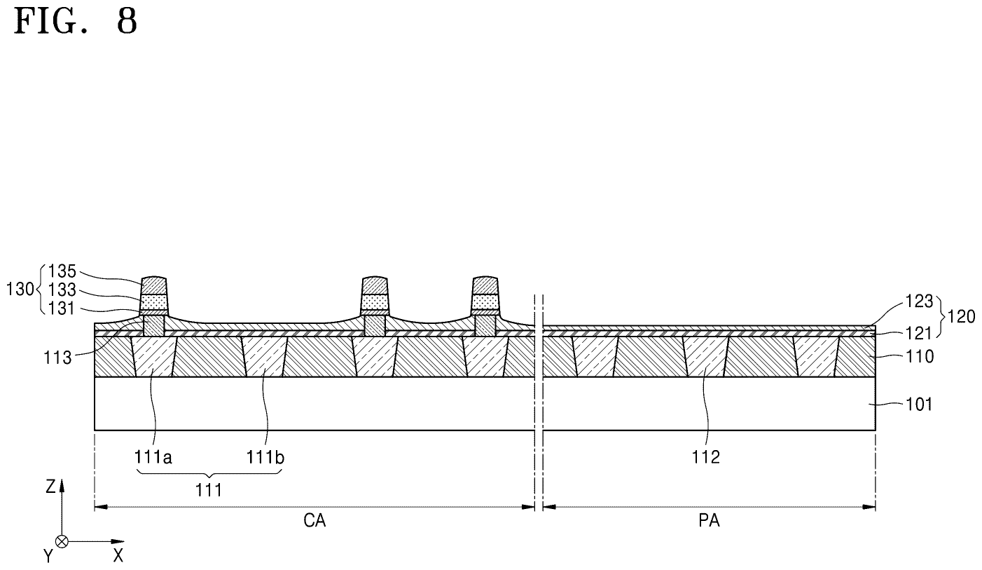

Referring to FIG. 8, in the cell area CA, an MTJ structure 130 that contacts the pad electrode 113 and is electrically connected to the pad electrode 113 may be formed.

The MTJ structure 130 may be disposed at a cross-point of a first direction X and a second direction Y in a mesh structure. Also, the MTJ structure 130 may constitute a memory cell. The MTJ structure 130 may be formed only on the cell plug 111a from among the plurality of first plugs 111 in the cell area CA. In other words, the MTJ structure 130 may be electrically connected to the cell plug 111a through the pad electrode 113.

According to some embodiments, the MTJ structure 130 may have a structure in which a lower electrode 131, an MTJ pattern 133, and an upper electrode 135 are stacked. The MTJ pattern 133 constitutes a variable resistance layer and, as described above with reference to FIGS. 2 and 3, may include the pinned layer PL, the tunnel barrier layer TBL, and the free layer FL. The lower electrode 131 and the upper electrode 135 may include a metal or a metal nitride.

According to some embodiments, a portion of the second lower insulation layer 123 may be etched together during the process of forming the MTJ structure 130, and thus the second lower insulation layer 123 may have a rounded top surface.

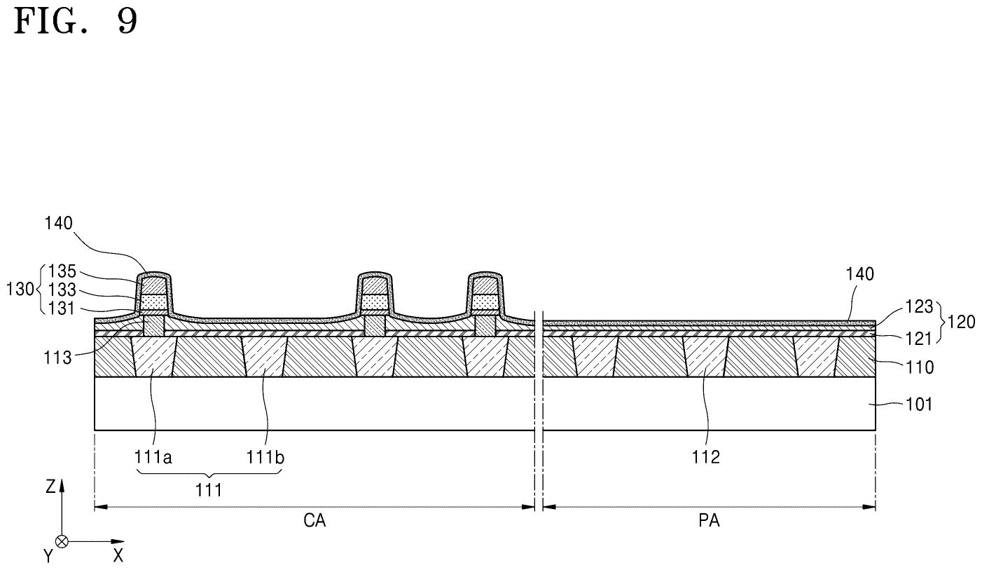

Referring to FIG. 9, a capping layer 140 that conformally is on and at least partially covers the entirety of the MTJ structure 130 and the top surface of the lower insulation layer 120 may be formed over the cell area CA and peripheral area PA.

The capping layer 140 may be formed to protect the MTJ structure 130. The capping layer 140 is on and at least partially covers both the top surface and side surfaces of the MTJ structure 130 and may extend between MTJ structures 130 adjacent to each other. Therefore, the capping layer 140 may be referred to as an encapsulation layer.

The capping layer 140 may include an insulation material. For example, the capping layer 140 may include silicon nitride (SiN).

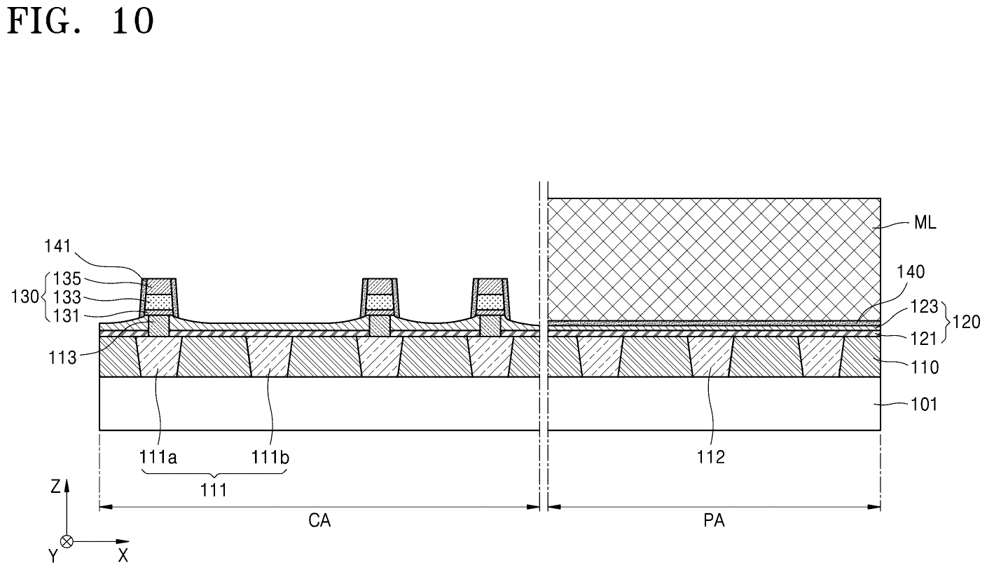

Referring to FIG. 10, a mask layer ML may be formed in the peripheral area PA, and a capping pattern 141 may be formed on both sidewalls of the MTJ structure 130 in the cell area CA through an entire surface etching process.

By forming the mask layer ML in the peripheral area PA, the peripheral area PA may not be etched through the entire surface etching process. In contrast, because the mask layer ML is not formed in the cell area CA, a significant portion of the capping layer 140 (refer to FIG. 9) located at the top of the cell area CA may be etched through the entire surface etching process.

When the entire surface etching process is anisotropic etching, e.g., dry etching, the capping pattern 141 may be formed on both sidewalls of the MTJ structure 130. Through the entire surface etching process, the top surface of the MTJ structure 130 and the rounded top surface of the second lower insulation layer 123 may be at least partially exposed to the outside in the cell area CA.

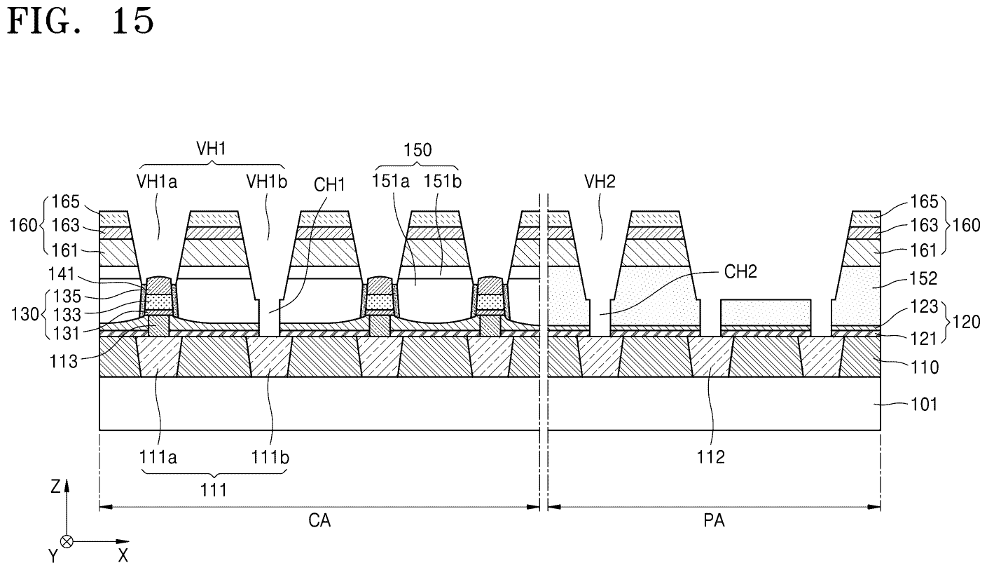

By removing the capping layer 140 (refer to FIG. 9) while leaving only the capping pattern 141 on both sidewalls of the MTJ structure 130, the difference in etch profiles that occurs in the subsequent process of forming a first contact hole CH1 and a second contact hole CH2 (refer to FIG. 15) simultaneously in the cell area CA and the peripheral area PA may be reduced.

Also, by etching the capping layer 140 (refer to FIG. 9) extending between the MTJ structures 130 adjacent to each other, conductive etching by-products existing on the top surface and/or the bottom surface of the capping layer 140 (refer to FIG. 9) may be removed together, thereby preventing or reducing the flow of a leakage current between the MTJ structures 130.

Next, the mask layer ML may be completely removed through an ashing and stripping process.

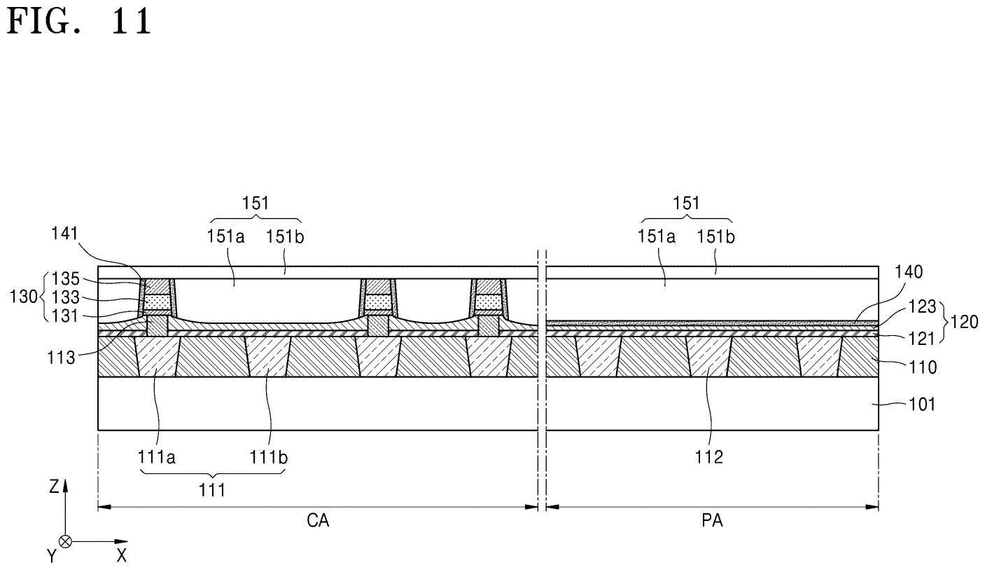

Referring to FIG. 11, a buried insulation layer 151 may be formed over the cell area CA and the peripheral area PA.

The buried insulation layer 151 may include a first buried insulation layer 151a and a second buried insulation layer 151b formed on the first buried insulation layer 151a. The first buried insulation layer 151a and the second buried insulation layer 151b may include different materials.

In the cell area CA, the first buried insulation layer 151a may at least partially fill the space between the MTJ structures 130 without voids. Also, the second buried insulation layer 151b may be formed to be on and at least partially cover the top surface of the MTJ structure 130.

According to some embodiments, the first buried insulation layer 151a may include silicon oxide (SiO) formed through a high density plasma (HDP) chemical vapor deposition process, but is not limited thereto.

According to some embodiments, the second buried insulation layer 151b may include a SiCN film, a SiOC film, a SiOF film, a SiCH film, a SiOCH film, or a combination thereof.

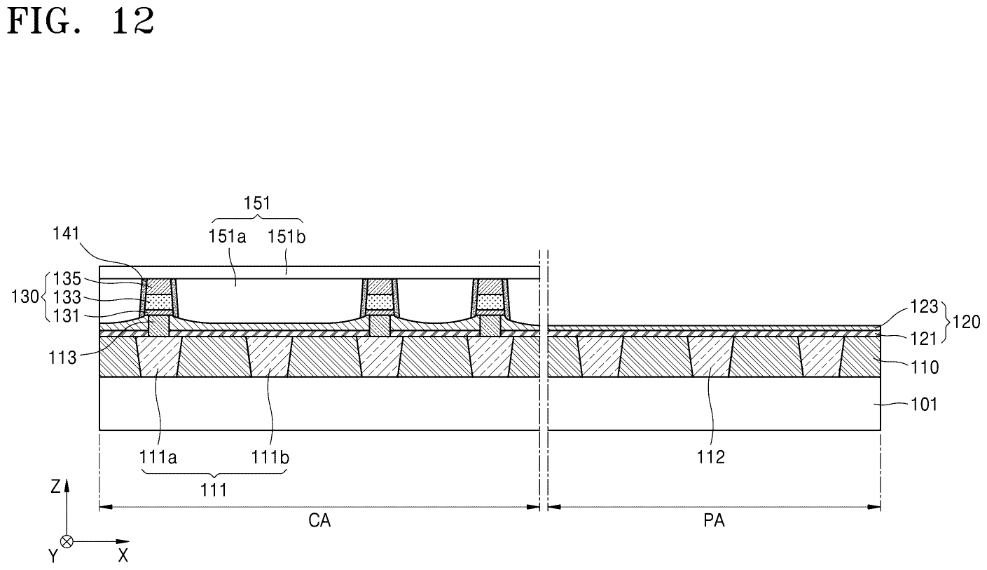

Referring to FIG. 12, the buried insulation layer 151 and the capping layer 140 (refer to FIG. 11) may be removed from the peripheral area PA.

Although not shown, a mask layer (not shown) on and at least partially covering the entire cell area CA may be formed. By forming the mask layer in the cell area CA, the buried insulation layer 151 may not be removed from the cell area CA.

In contrast, by not forming the mask layer in the peripheral area PA, the second buried insulation layer 151b and the first buried insulation layer 151a may be removed by using the capping layer 140 (refer to FIG. 11) as an etch stop layer in the peripheral area PA.

Next, the capping layer 140 (refer to FIG. 11) used as the etch stop layer in the peripheral area PA may be removed. Therefore, the flat top surface of the second lower insulation layer 123 may be at least partially exposed to the outside in the peripheral area PA.

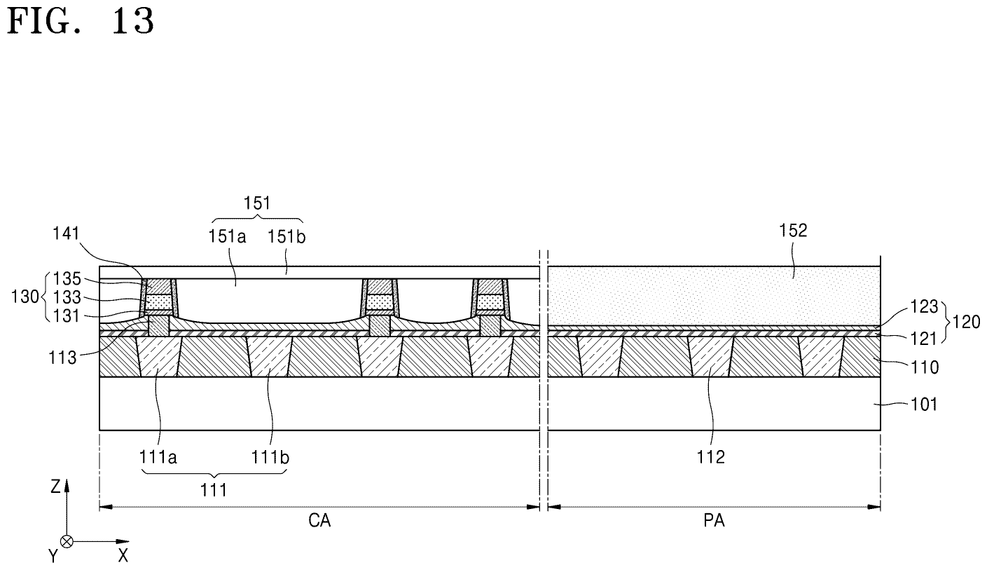

Referring to FIG. 13, an interlayer insulation layer 152 on and at least partially covering the top surface of the second lower insulation layer 123 may be formed in the peripheral area PA.

The interlayer insulation layer 152 formed in the peripheral area PA may include a material different from the material constituting the buried insulation layer 151 in the cell area CA.

According to some embodiments, the interlayer insulation layer 152 may include a material with a low dielectric constant that is lower than that of silicon oxide. The interlayer insulation layer 152 may include a material having a low dielectric constant of less than 3.9, e.g., a low-k (LK) dielectric, an ultra low-k (ULK) dielectric, an extreme low-k (ELK) dielectric, etc.

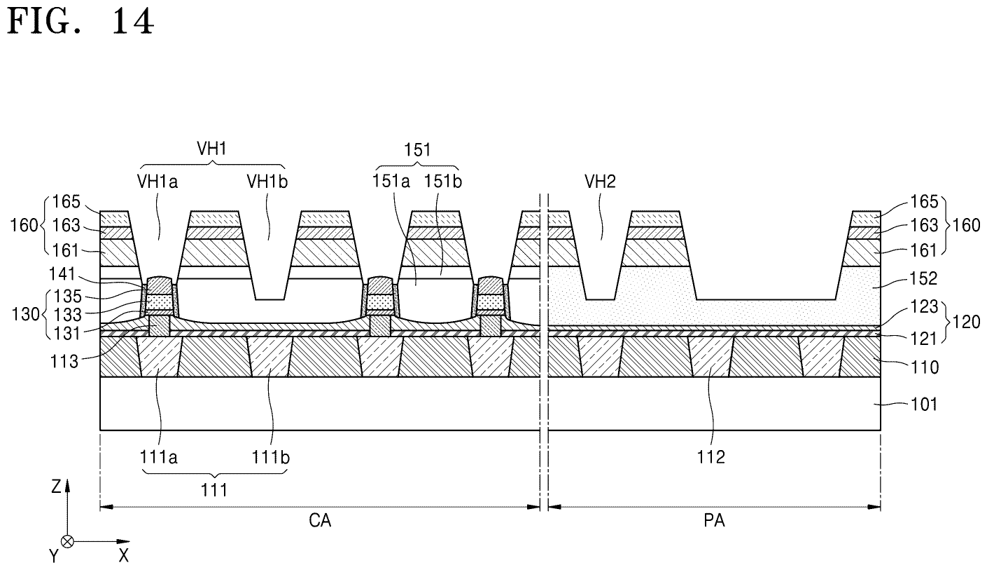

Referring to FIG. 14, an upper insulation layer 160 on and at least partially covering the buried insulation layer 151 in the cell area CA and on and at least partially covering the interlayer insulation layer 152 in the peripheral area PA may be formed.

The upper insulation layer 160 may include a first upper insulation layer 161, a second upper insulation layer 163 formed on the first upper insulation layer 161, and a third upper insulation layer 165 formed on the second upper insulation layer 163. The first upper insulation layer 161, the second upper insulation layer 163, and the third upper insulation layer 165 may include different materials from one another.

According to some embodiments, the first upper insulation layer 161 may include a tetraethoxysilane (TEOS) film, but is not limited thereto.

According to some embodiments, the second upper insulation layer 163 and the third upper insulation layer 165 may each include a SiON film, a SiOC film, a SiOF film, a SiCH film, a SiOCH film, or a combination thereof.

Next, a plurality of first via holes VH1 overlapping the plurality of first plugs 111 in a vertical direction Z may be formed in the cell area CA, and a plurality of second via holes VH2 overlapping the plurality of second plugs 112 in the vertical direction Z may be formed in the peripheral area PA.

The plurality of first via holes VH1 and the plurality of second via holes VH2 may each have a tapered shape that has a horizontal width that gradually decreases toward the substrate 101 in the vertical direction Z.

The plurality of first via holes VH1 include a first shallow via hole VH1a that overlaps the cell plug 111a in the vertical direction Z and a first deep via hole VH1b that overlaps the via plug 111b in the vertical direction Z.

Here, since the etching of the first shallow via hole VH1a is stopped by the top surface of the MTJ structure 130, the depth of the first shallow via hole VH1a may be less than the depth of the first deep via hole VH1b. In other words, the top surface of the MTJ structure 130 may be exposed to the outside by the first shallow via hole VH1a.

The plurality of second via holes VH2 may have different horizontal widths in the first direction X from one another. In other words, some of the plurality of second via holes VH2 may have a greater horizontal width than the remaining second via holes VH2.

Referring to FIG. 15, the first contact hole CH1 may be formed by etching the bottom surface of the first deep via hole VH1b in the cell area CA, and second contact holes CH2 may be formed by etching the bottom surfaces of the plurality of second via holes VH2 in the peripheral area PA.

The first contact hole CH1 at least partially exposing the top surface of the via plug 111b may be formed by etching a portion of the bottom surface of the first deep via hole VH1b that overlaps the via plug 111b in the vertical direction Z in the cell area CA.

Because the bottom surface of the first shallow via hole VH1a that overlaps the cell plug 111a in the vertical direction Z in the cell area CA is the top surface of the MTJ structure 130, the bottom surface of the first shallow via hole VH1a may not be etched.

In the cell area CA, a first via hole VH1 may alone at least partially expose the top surface of the MTJ structure 130, or the first via hole VH1 may at least partially expose the top surface of the via plug 111b together with the first contact hole CH1.

The second contact holes CH2 at least partially exposing the top surfaces of the plurality of second plugs 112 may be formed by etching the bottom surfaces of the plurality of second via holes VH2 in the peripheral area PA. One second contact hole CH2 may be formed in each of some of the plurality of second via holes VH2, and two second contact holes CH2 may be formed in each of the remaining second via holes VH2. However, embodiments of the inventive concept are not limited thereto.

In the peripheral area PA, a second via hole VH2 may expose the top surfaces of a second plug 112 together with the second contact hole CH2.

Here, the capping layer 140 (refer to FIG. 9) may not exist on the inner sidewall of the first contact hole CH1 and the inner sidewall of the second contact hole CH2.

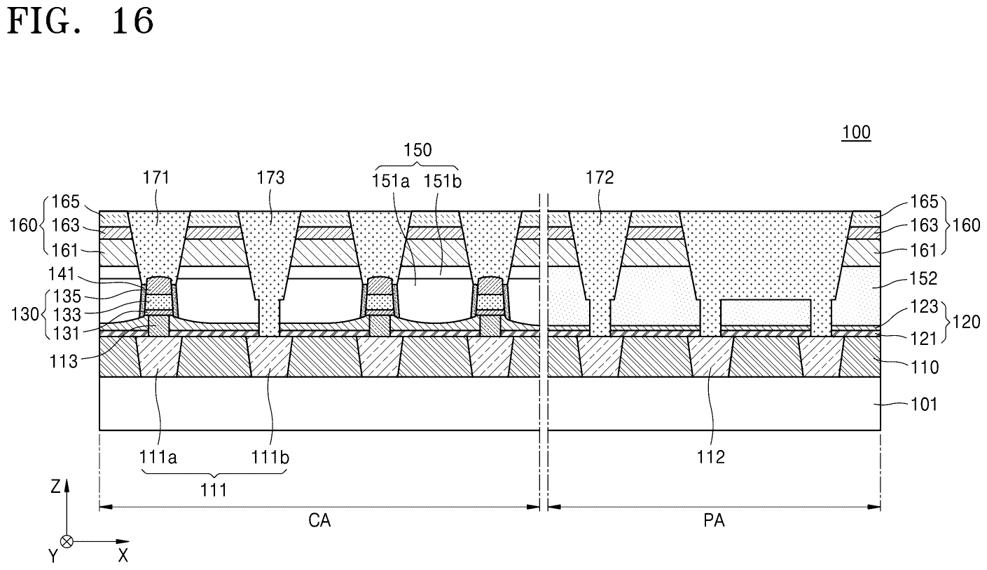

Referring to FIG. 16, a metal layer that at least partially fills the plurality of first via holes VH1 (refer to FIG. 15) and the first contact hole CH1 (refer to FIG. 15) in the cell area CA and at least partially fills the plurality of second via holes VH2 (refer to FIG. 15) and the second contact hole CH2 (refer to FIG. 15) in the peripheral area PA may be formed.

After the process of forming the metal layer, the metal layer may be separated into nodes, thereby forming a first contact 171 contacting the MTJ structure 130 and a cell via 173 contacting the via plug 111b in the cell area CA. At the same time, a second contact 172 contacting the second plug 112 may be formed in the peripheral area PA.

Here, in the cell area CA, the cell via 173 may be formed between MTJ structures 130 adjacent to each other. Also, the vertical, i.e., Z direction, length of the cell via 173 may be substantially identical to the vertical length of the second contact 172, and the vertical length of the first contact 171 may be less than the vertical length of the second contact 172.

Through the above-stated fabricating process, a variable resistance memory device 100 according to some embodiments of the inventive concept may be fabricated.

According to the demand for the highly-integrated variable resistance memory device 100 and the development of fabricating process technology, the pitch between neighboring magnetoresistive memory cells 10u (refer to FIG. 1) is decreasing. Therefore, to lower the metal line resistance and the cell resistance in the variable resistance memory device 100, there is a trend to form the cell via 173 between the MTJ structures 130.

Differences between mold insulation layers (e.g., a lower insulation layer, a buried insulation layer, an interlayer insulation layer, and an upper insulation layer) constituting the cell area CA and the peripheral area PA may occur during the process of forming the cell via 173, and, in particular, silicon nitride constituting the capping layer 140 (refer to FIG. 11) may not exist in the peripheral area PA. Therefore, when the first contact hole CH1 and the second contact hole CH2 are etched simultaneously in the cell area CA and the peripheral area PA, it may be difficult to form the same etch profile.

To address this problem, a method of fabricating the variable resistance memory device 100 according to some embodiments of the inventive concept includes a process of removing the capping layer 140 (refer to FIG. 11) in advance from an area where the cell via 173 is to be formed.

Ultimately, according to the method of fabricating the variable resistance memory device 100 according to some embodiments of the inventive concept, by forming a mold insulation layer from materials with similar etch selectivity in the cell area CA and the peripheral area PA, the difference between etch profiles that occurs during formation of the first contact hole CH1 and the second contact hole CH2 simultaneously in the cell area CA and the peripheral area PA may be reduced.

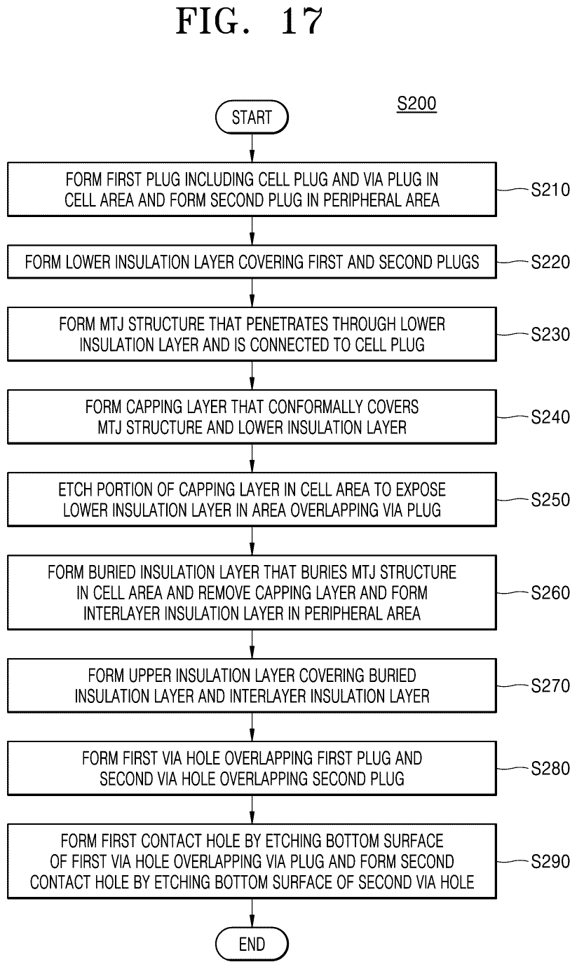

FIG. 17 is a flowchart of a method of fabricating a variable resistance memory device according to another embodiment.

Referring to FIG. 17, a method S200 of fabricating a variable resistance memory device may include first to ninth operations S210 to S290.

The method S200 of fabricating a variable resistance memory device according to embodiments of the inventive concept may include a first operation S210 of forming a first plug including a first cell plug and a first via plug in a cell area and forming a second plug in a peripheral area, a second operation S220 of forming a lower insulation layer on and at least partially covering the first plug and the second plug, a third operation S230 of forming an MTJ structure that penetrates or extends through the lower insulation layer and is connected to the first cell plug, a fourth operation S240 of forming a capping layer that conformally is on and at least partially covers the MTJ structure and the lower insulation layer, a fifth operation S250 of etching a portion of the capping layer to at least partially expose the lower insulation layer in an area overlapping the first via plug in the vertical or Z direction, a sixth operation S260 of forming a buried insulation layer that is on the MTJ structure in the cell area and removing the capping layer and forming an interlayer insulation layer in the peripheral area, a seventh operation S270 of forming an upper insulation layer that is on and at least partially covers the buried insulation layer and the interlayer insulation layer, an eighth operation S280 of forming a first via hole overlapping the first plug in the vertical or Z direction and a second via hole overlapping the second plug in the vertical or Z direction, and a ninth operation S290 of forming a first contact hole by etching the bottom surface of the first via hole overlapping the first via plug in the vertical or Z direction and forming a second contact hole by etching the bottom surface of the second via hole.

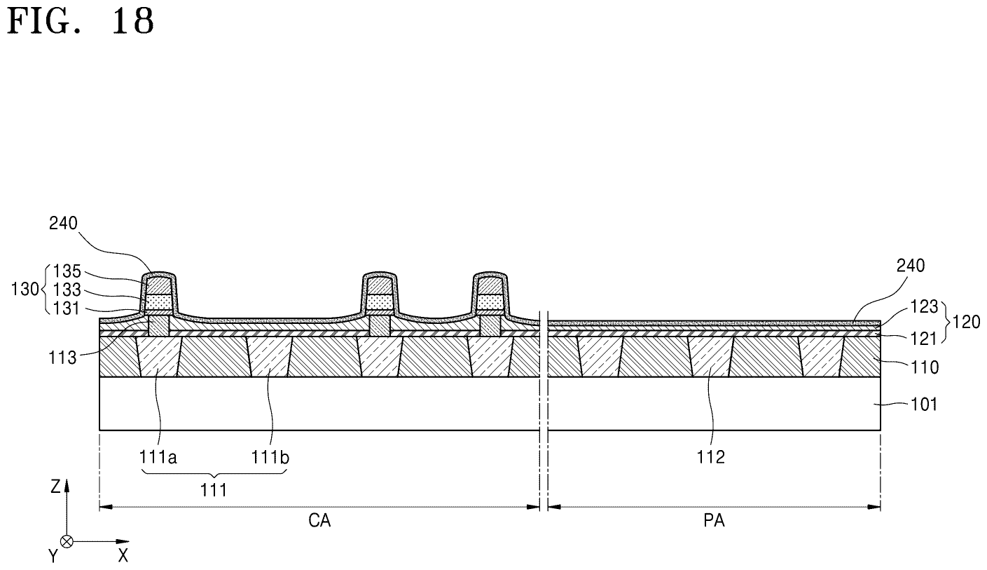

The technical features of each of first to ninth operations S210 to S290 are described below in detail with reference to FIGS. 18 to 22.

FIGS. 18 to 22 are cross-sectional views illustrating a method of fabricating a variable resistance memory device according to another embodiment according to a process sequence.

The method of forming most of the components included in the method of fabricating a variable resistance memory device 200 described below is substantially identical or similar to that previously described with reference to FIGS. 6 to 16. Therefore, for convenience of explanation, descriptions below will focus on differences from the method of fabricating the variable resistance memory device 100 described above.

Referring to FIG. 18, a capping layer 240 that conformally is on and at least partially covers the entirety of the MTJ structure 130 and the top surface of the lower insulation layer 120 may be formed over the cell area CA and peripheral area PA.

The capping layer 240 may be formed to protect the MTJ structure 130. The capping layer 240 is on and at least partially covers both the top surface and side surfaces of the MTJ structure 130 and may extend between MTJ structures 130 adjacent to each other. Therefore, the capping layer 240 may be referred to as an encapsulation layer.

The capping layer 240 may include an insulation material. For example, the capping layer 240 may include silicon nitride (SiN).

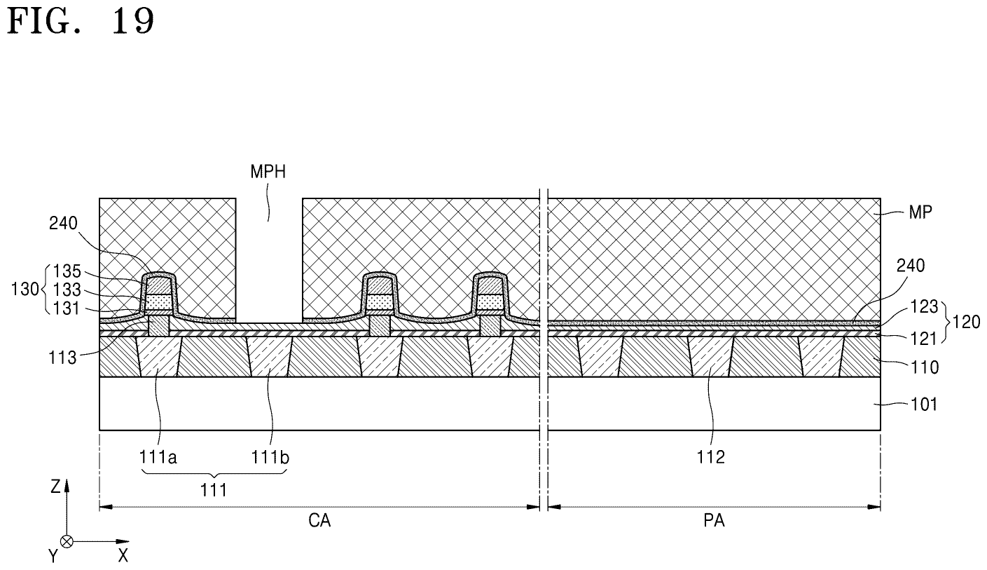

Referring to FIG. 19, a mask pattern MP may be formed over the cell area CA and the peripheral area PA to at least partially expose an area overlapping the via plug 111b in the Z direction.

By performing an etching process to remove a portion of the capping layer 240 using the mask pattern MP having a pattern hole MPH that exposes only the area overlapping the via plug 111b as an etch mask in the cell area CA, the top surface of the second lower insulation layer 123 may be at least partially exposed to the outside only in the area overlapping the via plug 111b in the Z direction.

By removing the capping layer 240 from the area overlapping the via plug 111b, the difference between etch profiles that occurs during a subsequent process of forming the first contact hole CH1 and the second contact hole CH2 simultaneously in the cell area CA and the peripheral area PA may be reduced.

Although not shown, according to other embodiments, the mask pattern MP may be formed to expose the capping layer 240 at the edge area of the substrate 101. Therefore, popping defects that may occur in the edge area of the substrate 101 during the etching process may be simultaneously removed.

Next, the mask pattern MP may be completely removed through an ashing and stripping process.

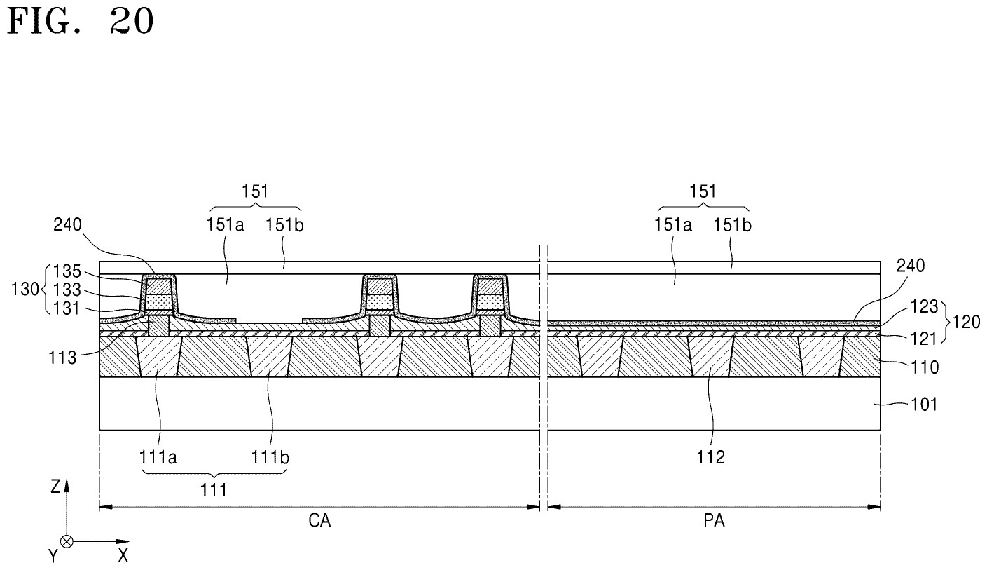

Referring to FIG. 20, the buried insulation layer 151 may be formed over the cell area CA and the peripheral area PA.

The buried insulation layer 151 may include the first buried insulation layer 151a and the second buried insulation layer 151b formed on the first buried insulation layer 151a. The first buried insulation layer 151a and the second buried insulation layer 151b may include different materials.

In the cell area CA, the first buried insulation layer 151a may at least partially fill the space between the MTJ structures 130 without voids. Also, the second buried insulation layer 151b may be formed to be on and at least partially cover the top surface of the capping layer 240.

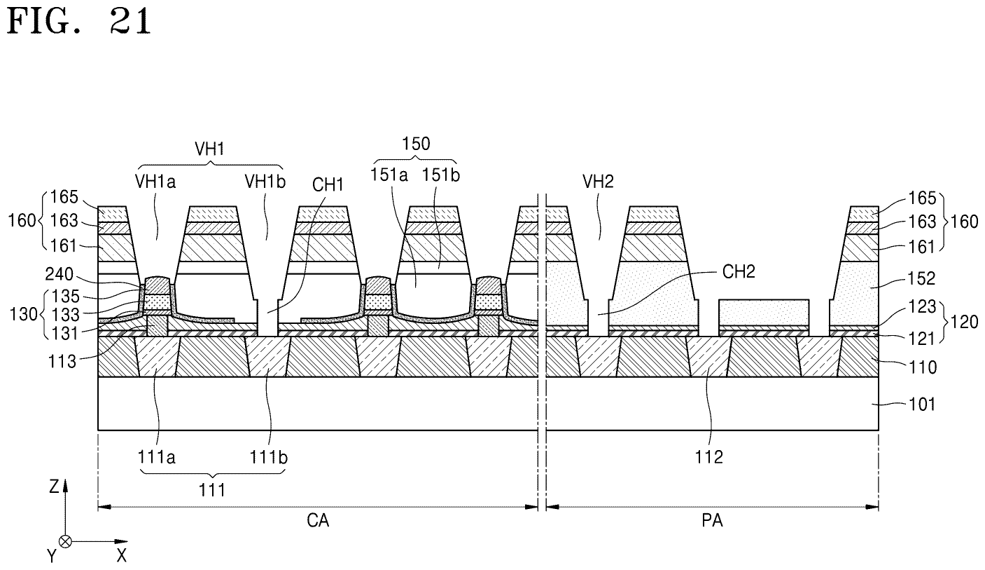

Referring to FIG. 21, the upper insulation layer 160 on and at least partially covering the buried insulation layer 151 in the cell area CA and on and at least partially covering the interlayer insulation layer 152 in the peripheral area PA may be formed.

The upper insulation layer 160 may include the first upper insulation layer 161, the second upper insulation layer 163 formed on the first upper insulation layer 161, and the third upper insulation layer 165 formed on the second upper insulation layer 163. The first upper insulation layer 161, the second upper insulation layer 163, and the third upper insulation layer 165 may include different materials from one another.

Next, the plurality of first via holes VH1 overlapping the plurality of first plugs 111 in the vertical direction Z may be formed in the cell area CA, and the plurality of second via holes VH2 overlapping the plurality of second plugs 112 in the vertical direction Z may be formed in the peripheral area PA.

Next, the first contact hole CH1 may be formed by etching the bottom surface of the first deep via hole VH1b in the cell area CA, and the second contact holes CH2 may be formed by etching the bottom surfaces of the plurality of second via holes VH2 in the peripheral area PA.

Here, the capping layer 240 may not exist on the inner sidewall of the first contact hole CH1 and the inner sidewall of the second contact hole CH2.

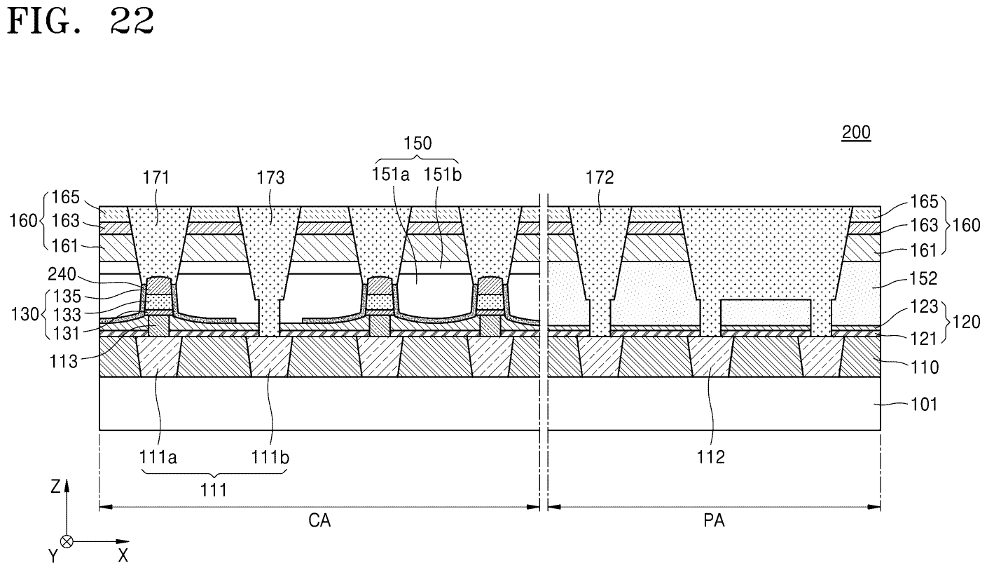

Referring to FIG. 22, a metal layer that at least partially fills the plurality of first via holes VH1 (refer to FIG. 21) and the first contact hole CH1 (refer to FIG. 21) in the cell area CA and at least partially fills the plurality of second via holes VH2 (refer to FIG. 21) and the second contact hole CH2 (refer to FIG. 21) in the peripheral area PA may be formed.

After the process of forming the metal layer, the metal layer may be separated into nodes, thereby forming the first contact 171 contacting the MTJ structure 130 and the cell via 173 contacting the via plug 111b in the cell area CA. At the same time, the second contact 172 contacting the second plug 112 may be formed in the peripheral area PA.

Here, in the cell area CA, the cell via 173 may be formed between MTJ structures 130 adjacent to each other. Also, the vertical, i.e., Z direction, length of the cell via 173 may be substantially identical to the vertical length of the second contact 172, and the vertical length of the first contact 171 may be less than the vertical length of the second contact 172.

The capping layer 240 extends continuously between the MTJ structures 130 that are adjacent to each other in the cell area CA, but the capping layer 240 may extend discontinuously in the area where the cell via 173 is formed.

Through the above-stated fabricating process, the variable resistance memory device 200 according to some embodiments of the inventive concept may be fabricated.

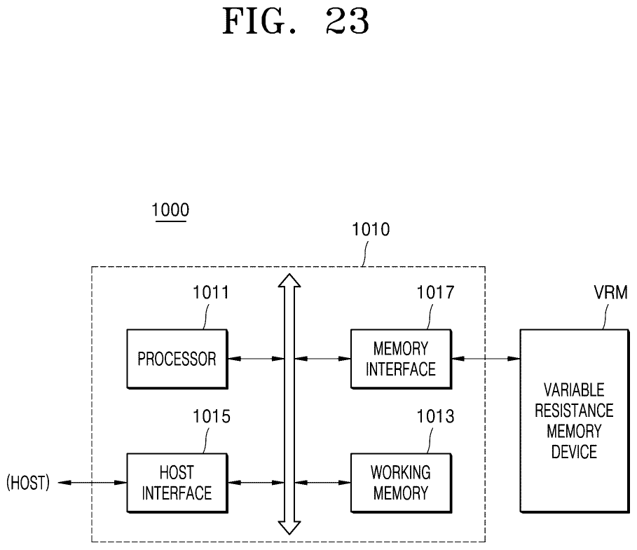

FIG. 23 is a configuration diagram showing a data processing system including a variable resistance memory element according to an embodiment.

Referring to FIG. 23, a data processing system 1000 may include a memory controller 1010 connected between a host and a variable resistance memory device VRM.

The memory controller 1010 may be configured to access the variable resistance memory device VRM in response to a request of the host.

The variable resistance memory device VRM may include any one of variable resistance memory devices 100 and 200 fabricated according to the above-stated methods S100 and S200 of fabricating a variable resistance memory device. The memory controller 1010 may include a processor 1011, a working memory 1013, a host interface 1015, and a memory interface 1017.

The processor 1011 controls the overall operation of the memory controller 1010, and the working memory 1013 may store applications, data, and control signals needed for the operation of the memory controller 1010. The host interface 1015 may perform protocol conversion for data/control signal exchange between the host and the memory controller 1010.

The memory interface 1017 may perform protocol conversion for data/control signal exchange between the memory controller 1010 and the variable resistance memory device VRM. Since the configuration and the operating characteristics of the variable resistance memory device VRM are identical to those described above, detailed descriptions thereof are omitted.

The data processing system 1000 according to an embodiment may be a memory card, but is not limited thereto.

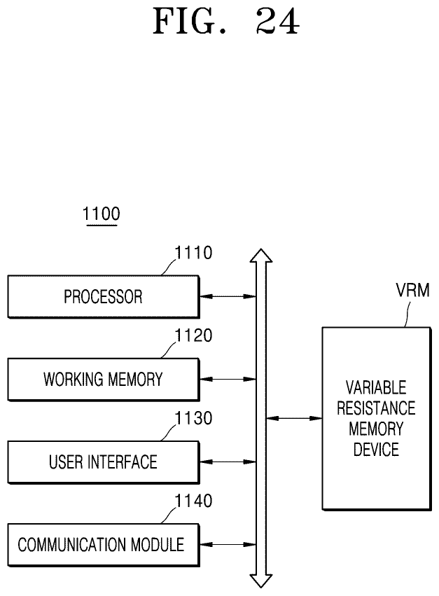

FIG. 24 is a configuration diagram showing a data processing system including a variable resistance memory element according to an embodiment.

Referring to FIG. 24, a data processing system 1100 may include a variable resistance memory device VRM, a processor 1110, a working memory 1120, and a user interface 1130, and, as needed, may further include a communication module 1140.

The variable resistance memory device VRM may include any one of variable resistance memory devices 100 and 200 fabricated according to the above-stated methods S100 and S200 of fabricating a variable resistance memory device.

The processor 1110 may be a central processing unit. The working memory 1120 stores application programs, data, control signals, etc. needed for the operation of the data processing system 1100. The user interface 1130 provides an environment in which a user may access the data processing system 1100 and provides data processing processes and processing results of the data processing system 1100 to the user. Because the configuration and the operating characteristics of the variable resistance memory device VRM are identical to those described above, detailed descriptions thereof are omitted.

The data processing system 1100 may be used as a disk device, as an internal/external memory card of a portable electronic device, as an image processor, or as an application chipset.

While the inventive concept has been particularly shown and described with reference to embodiments thereof, it will be understood that various changes in form and details may be made therein without departing from the spirit and scope of the following claims.

What is claimed is:

1. A method of fabricating a variable resistance memory device, comprising:
preparing a substrate having a cell area and a peripheral area surrounding the cell area in a plan view;
forming a first plug comprising a first cell plug and a first via plug in the cell area and forming a second plug in the peripheral area;
forming a lower insulation layer on the first plug and the second plug over the cell area and the peripheral area;
forming a magnetic tunnel junction (MTJ) structure that extends through the lower insulation layer in the cell area and is electrically connected to the first cell plug;
forming a capping layer conformally on the MTJ structure and the lower insulation layer over the cell area and the peripheral area;
forming a capping pattern on both sidewalls of the MTJ structure by anisotropically etching the capping layer in the cell area;
forming a buried insulation layer on the MTJ structure in the cell area and removing the capping layer from the peripheral area;
forming an interlayer insulation layer on the lower insulation layer in the peripheral area;
forming an upper insulation layer on the buried insulation layer in the cell area and on the interlayer insulation layer in the peripheral area;
forming a first via hole overlapping the first plug in the cell area in a direction perpendicular to an upper surface of the substrate and forming a second via hole overlapping the second plug in the peripheral area in the direction perpendicular to the upper surface of the substrate; and
forming a first contact hole by etching a bottom surface of the first via hole that overlaps the first via plug in the cell area in the direction perpendicular to the upper surface of the substrate and forming a second contact hole by etching a bottom surface of the second via hole in the peripheral area.

2. The method of claim 1, wherein, in the forming of the first contact hole and the second contact hole, the capping layer is not present on an inner sidewall of the first contact hole in the cell area and an inner sidewall of the second contact hole in the peripheral area.

3. The method of claim 1, wherein, in the forming of the first contact hole and the second contact hole, in the cell area, the first via hole alone exposes at least a portion of a top surface of the MTJ structure, or the first via hole exposes at least a portion of a top surface of the first via plug together with the first contact hole, and,
in the peripheral area, the second via hole exposes at least a portion of a top surface of the second plug together with the second contact hole.

4. The method of claim 3, further comprising, after the forming of the first contact hole and the second contact hole, forming a metal layer that at least partially fills the first via hole and the first contact hole in the cell area and at least partially fills the second via hole and the second contact hole in the peripheral area.

5. The method of claim 4, wherein, after the forming of the metal layer, the metal layer is separated into nodes to form a first contact in contact with the MTJ structure and a cell via in contact with the first via plug in the cell area, and form a second contact in contact with the second plug in the peripheral area.

6. The method of claim 5, wherein a vertical length of the cell via in the direction perpendicular to the upper surface of the substrate is identical to a vertical length of the second contact in the direction perpendicular to the upper surface of the substrate, and
a vertical length of the first contact is less than the vertical length of the second contact.

7. The method of claim 5, wherein the cell via is formed between MTJ structures that are adjacent to each other in the cell area.

8. The method of claim 1, wherein, in the forming of the capping pattern,
a portion of the capping layer is removed from the cell area to at least partially expose a top surface of the MTJ structure and a top surface of the lower insulation layer, but the capping layer is protected by a mask pattern in the peripheral area.

9. The method of claim 8, wherein the capping layer functions as an etch stop layer in the peripheral area.

10. The method of claim 1, wherein the buried insulation layer in the cell area and the interlayer insulation layer in the peripheral area are formed at a same vertical level relative to the upper surface of the substrate being a base reference plane, and the buried insulation layer comprises a different material from the interlayer insulation layer.

11. A method of fabricating a variable resistance memory device, the method comprising:
preparing a substrate having a cell area and a peripheral area surrounding the cell area in a plan view;
forming a first plug comprising a first cell plug and a first via plug in the cell area and forming a second plug in the peripheral area;
forming a lower insulation layer on the first plug and the second plug over the cell area and the peripheral area;
forming a magnetic tunnel junction (MTJ) structure that extends through the lower insulation layer in the cell area and is electrically connected to the first cell plug;
forming a capping layer conformally on the MTJ structure and the lower insulation layer over the cell area and the peripheral area;
forming a mask pattern over the cell area and the peripheral area to at least partially expose an area overlapping the first via plug in a direction perpendicular to an upper surface of the substrate;
at least partially exposing a lower insulation layer in the area overlapping the first via plug in the direction perpendicular to the upper surface of the substrate by etching a portion of the capping layer by using the mask pattern as an etching mask;
removing the mask pattern;
forming a buried insulation layer on the MTJ structure in the cell area and removing the capping layer from the peripheral area;
forming an interlayer insulation layer on the lower insulation layer in the peripheral area;
forming an upper insulation layer on the buried insulation layer in the cell area and on the interlayer insulation layer in the peripheral area;
forming a first via hole overlapping the first plug in the cell area in the direction perpendicular to the upper surface of the substrate and forming a second via hole overlapping the second plug in the peripheral area in the direction perpendicular to the upper surface of the substrate; and
forming a first contact hole by etching a bottom surface of the first via hole that overlaps the first via plug in the cell area in the direction perpendicular to the upper surface of the substrate and forming a second contact hole by etching a bottom surface of the second via hole in the peripheral area.

12. The method of claim 11, wherein, in the forming of the first via hole and the second via hole, in the cell area, the first via hole is formed by removing a portion of the capping layer to at least partially expose a top surface of the MTJ structure.

13. The method of claim 12, wherein, in the forming of the first contact hole and the second contact hole, in the cell area, the first via hole alone at least partially exposes a top surface of the MTJ structure, or the first via hole at least partially exposes a top surface of the first via plug together with the first contact hole, and,
in the peripheral area, the second via hole at least partially exposes a top surface of the second plug together with the second contact hole.

14. The method of claim 13, further comprising, after the forming of the first contact hole and the second contact hole, forming a metal layer that at least partially fills the first via hole and the first contact hole in the cell area and at least partially fills the second via hole and the second contact hole in the peripheral area.

15. The method of claim 14, wherein, after the forming of the metal layer, the metal layer is separated into nodes to form a first contact in contact with the MTJ structure and a cell via in contact with the first via plug in the cell area, and form a second contact in contact with the second plug in the peripheral area.

16. The method of claim 15, wherein the cell via is formed between MTJ structures that are adjacent to each other in the cell area.

17. The method of claim 16, wherein the capping layer extends continuously between the MTJ structures that are adjacent to each other in the cell area, but the capping layer extends discontinuously in the area where the cell via is formed.

18. The method of claim 11, wherein, in the forming of the mask pattern, the mask pattern at least partially exposes the capping layer at an edge area of the substrate.

19. A method of fabricating a variable resistance memory device, the method comprising:
preparing a substrate having a cell area and a peripheral area surrounding the cell area in a plan view;
forming a first plug comprising a first cell plug and a first via plug in the cell area and forming a second plug in the peripheral area;
forming a lower insulation layer on the first plug and the second plug over the cell area and the peripheral area;
forming a magnetic tunnel junction (MTJ) structure that extends through the lower insulation layer in the cell area and is electrically connected to the first cell plug;
forming a capping layer conformally on the MTJ structure and the lower insulation layer over the cell area and the peripheral area;
etching a portion of the capping layer to at least partially expose a lower insulation layer in an area overlapping the first via plug in a direction perpendicular to an upper surface of the substrate;
forming a buried insulation layer on the MTJ structure in the cell area and removing the capping layer from the peripheral area;
forming an interlayer insulation layer on the lower insulation layer in the peripheral area;
forming an upper insulation layer on the buried insulation layer in the cell area and on the interlayer insulation layer in the peripheral area;
forming a first via hole overlapping the first plug in the cell area in the direction perpendicular to the upper surface of the substrate and forming a second via hole overlapping the second plug in the peripheral area in the direction perpendicular to the upper surface of the substrate;
forming a first contact hole by etching a bottom surface of the first via hole that overlaps the first via plug in the cell area in the direction perpendicular to the upper surface of the substrate and forming a second contact hole by etching a bottom surface of the second via hole in the peripheral area;
forming a metal layer that at least partially fills the first via hole and the first contact hole in the cell area and at least partially fills the second via hole and the second contact hole in the peripheral area; and
separating the metal layer into nodes to form a first contact in contact with the MTJ structure and a cell via in contact with the first via plug in the cell area, and forming a second contact in contact with the second plug in the peripheral area.

20. The method of claim 19, wherein, in the forming of the first contact hole and the second contact hole, the first contact hole and the second contact hole are formed simultaneously,
wherein the first contact hole and the second contact hole have a same profile, and
wherein the capping layer is not present on an inner sidewall of the first contact hole in the cell area and an inner sidewall of the second contact hole in the peripheral area.
